(19) United States
(12) Patent Application Publication
(10) Pub. No.: US 2015/0293183 A1
(43) Pub. Date: Oct. 15, 2015

(54) BATTERY MANAGEMENT DEVICE, POWER SUPPLY, AND SOC ESTIMATION METHOD

(71) Applicant: SANYO Electric Co., Ltd., Osaka (JP)

(72) Inventors: HIROSHI TENMYO, Osaka (JP); MUTSUHIKO TAKEDA, Osaka (JP); SHIN-ICHI YUASA, Kyoto (JP)

(21) Appl. No.: 14/647,134

(22) PCT Filed: Nov. 28, 2013
(86) PCT No.: PCT/JP2013/007000

§ 371 Date: May 26, 2015

(30) Foreign Application Priority Data
Nov. 30, 2012 (JP) 2012-262597

(51) Int. Cl. G01R 31/36

(52) U.S. Cl. CPC G01R 31/3679; G01R 31/361; G01R 31/3655

(57) ABSTRACT

Current-integration estimation unit estimates the SOC of a battery by integrating the value of the current flowing through the battery. Open-circuit voltage estimation unit estimates the open-circuit voltage value of the battery from a value that includes at least the measured voltage value of the battery and indicates the state of the battery, and identifies the SOC corresponding to the open-circuit voltage value. In neither charged nor discharged state, SOC determination unit employs the SOC estimated by open-circuit voltage estimation unit. In charged or discharged state, SOC determination unit employs the SOC estimated by current-integration estimation unit without change or after correction using the SOC estimated by open-circuit voltage estimation unit. In parallel with the SOC estimation, SOH estimation unit estimates the SOH of the battery based on the variation value of the SOC employed by SOC determination unit and the integrated current value in the time period required for the variation.

### TECHNICAL FIELD

The present invention relates to a battery management device for managing the state of a battery, a power supply including the battery management device, and a state-of-charge (SOC) estimation method for estimating the SOC of the battery.

### BACKGROUND ART

Recently, a hybrid electric vehicle (HEV), a plug-in hybrid electric vehicle (PHEV), an electric vehicle (EV) have become widespread. These vehicles include a secondary battery as a key device. As an on-vehicle secondary battery, mainly, a nickel hydride battery and a lithium ion battery have become widespread. It is expected that, in the future, a lithium ion battery having a high energy density become widespread at an increasingly fast pace.

An on-vehicle secondary battery and a large energy storage system require a severe safety management and an effective utilization of the battery capacity compared with a notebook computer or a mobile phone. As a precondition, accurate SOC (charging rate) estimation is required. Typical examples of the SOC estimation method include an open circuit voltage (OCV) method, and a current integration method (this is also called Coulomb count method) (for example, Patent Literature 1).

### CITATION LIST

### Patent Literature

PTL 1: Unexamined Japanese Patent Publication No. S63-208773

PTL 2: Unexamined Japanese Patent Publication No. H6-342045

### SUMMARY OF THE INVENTION

When a secondary battery is not in use, the current integration method cannot be employed. When the secondary battery is in use (during charge or discharge), both of the OCV method and the current integration method can be employed. The value of the SOC estimated by the OCV method during use of the secondary battery is apt to fluctuate. For example, the power consumption of a vehicle including a secondary battery varies due to acceleration or deceleration. Regarding a large energy storage system, the power consumption of a load connected to the large energy storage system varies. When the variation in the power consumption cannot be sufficiently grasped, the value of the SOC estimated by the OCV method is apt to fluctuate. In a vehicle including a regenerative brake, switch between the discharge by travelling and the charge by the regenerative brake is performed frequently, so that the SOC value is more apt to fluctuate. While, in the current integration method, the fluctuation becomes small, but accumulation of errors of a current sensor (e.g. hall element) reduces the accuracy.

The present invention addresses such situations. The purpose of the present invention is to provide a technology of accurately estimating the SOC.

In order to address the problems, a battery management device of an aspect of the present invention includes: a current-integration estimation unit for estimating the SOC of a battery by integrating the value of the current flowing through the battery; an open-circuit voltage estimation unit for estimating the open-circuit voltage value of the battery from a value that includes at least the measured voltage value of the battery and indicates the state of the battery, and identifying the SOC corresponding to the open-circuit voltage value; an SOC determination unit that, while the battery is being neither charged nor discharged, employs the SOC estimated by the open-circuit voltage estimation unit, and, while the battery is being charged or discharged, employs the SOC estimated by the current-integration estimation unit without change or after correction using the SOC estimated by the open-circuit voltage estimation unit; and a state-of-health (SOH) estimation unit that, in parallel with the SOC estimation, estimates the SOH of the battery based on the variation value of the SOC employed by the SOC determination unit and the integrated current value in the time period required for the variation.

### BRIEF DESCRIPTION OF DRAWINGS

FIG. 1 is a diagram for illustrating a power supply in accordance with an exemplary embodiment of the present invention.

FIG. 2 is a diagram showing an example of the SOC determination processing by an SOC determination unit.

FIG. 3 is a diagram showing the relationship between the discharge capacity and the SOC during discharge.

FIG. 4 is a diagram showing a temperature correction table and a current correction table.

FIG. 5 is a flowchart for illustrating an SOC estimation processing by a battery management device in accordance with the exemplary embodiment of the present invention.

### DESCRIPTION OF EMBODIMENT(S)

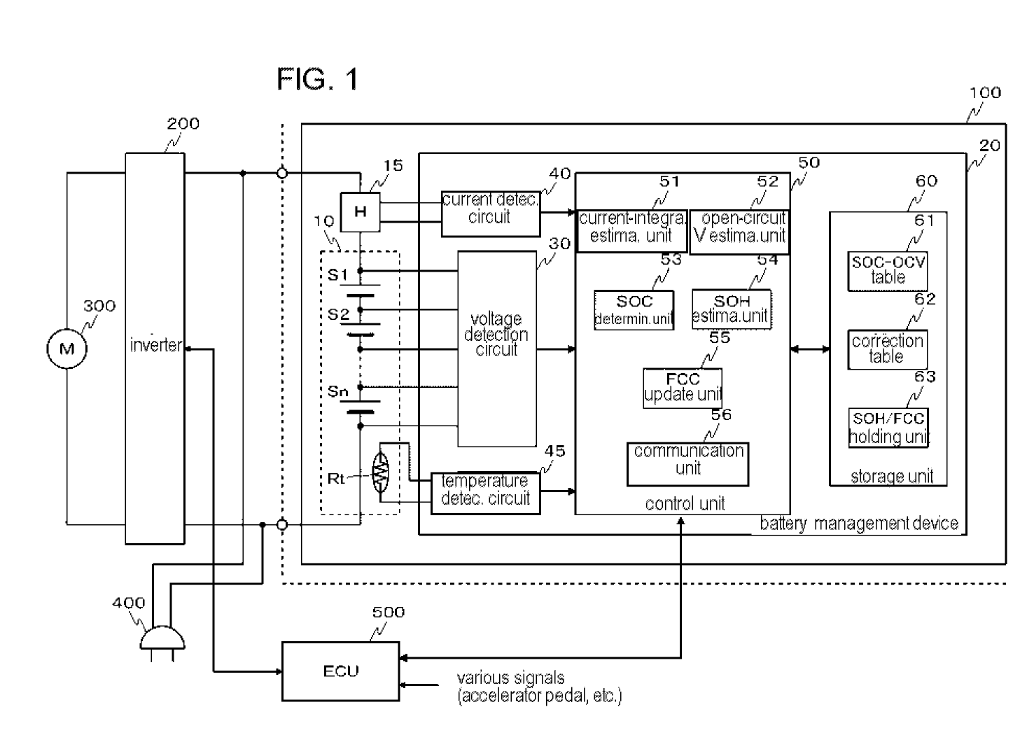

FIG. 1 is a diagram for illustrating power supply 100 in accordance with an exemplary embodiment of the present invention. The present description assumes an example where power supply 100 is mounted as a power source in a vehicle such as an HEV, PHEV, or EV. The present exemplary embodiment assumes an EV.

A three-phase alternating current (AC) synchronous motor is generally used for motor 300 for travelling. Inverter 200 is disposed between power supply 100 and motor 300 for travelling. During power running, inverter 200 converts the direct current (DC) power supplied from power supply 100 into AC power, and supplies the AC power to motor 300 for travelling. During regeneration, inverter 200 converts the AC power supplied from motor 300 for travelling into DC power, and supplies the DC power to power supply 100.

Charging plug 400 is connected to power supply 100 via an AC-DC converter (not shown). Charging plug 400 is connected to a typical outlet disposed in a house or an office, and secondary battery 10 in power supply 100 is normally charged by a commercial power source (AC power source). When charging plug 400 is connected to an outlet of a rapid charge stand, secondary battery 10 is rapidly charged.

Electronic control unit (ECU) 500 electronically controls the whole vehicle. ECU 500 controls inverter 200 on the basis of various signals input from an accelerator pedal, power supply 100, various auxiliary machines, and various sensors. A basic operation is as follows. When the accelerator pedal is pressed, ECU 500 controls inverter 200 so that inverter 200 supplies electric power corresponding to the degree of pressing to motor 300 for travelling. When the accelerator pedal is released, ECU 500 controls inverter 200 so that inverter 200 supplies, to power supply 100, the electric power that is generated from the deceleration energy serving as the energy source by the motor 300 for travelling.

Secondary battery 10 in power supply 100 is charged or discharged by the above-mentioned external charge and the power-running/regeneration control of inverter 200. In order to avoid overcharge and over-discharge, ECU 500 is required to accurately recognize the SOC of secondary battery 10. In order to extend the travel distance of the EV, the capacity of secondary battery 10 is required to be sufficiently utilized. In order to achieve the sufficient utilization, it is important to accurately recognize the SOC.

Power supply 100 includes secondary battery 10 and battery management device 20. Secondary battery 10 is a battery for storing energy for travelling. Battery management device 20 manages secondary battery 10. The present description assumes that a lithium ion battery is used as secondary battery 10. Secondary battery 10 is formed by interconnecting a plurality of battery cells S1 to Sn in series or in parallel. The positive terminals and negative terminals of the plurality of battery cells S1 to Sn are connected to a DC-side positive terminal and a DC-side negative terminal of inverter 200, respectively, via a contactor (not shown).

Hall element 15 as a current detection element is inserted into a current path that connects the plurality of battery cells S1 to Sn to inverter 200. A shunt resistance may be used instead of hall element 15. Thermistor Rt is disposed as a temperature detection element in a stack in which the plurality of battery cells S1 to Sn are mounted.

Voltage detection circuit 30 detects the voltage of each of battery cells S1 to Sn constituting secondary battery 10. Voltage detection circuit 30 outputs the detected voltage value of each cell to control unit 50.

Current detection circuit 40 detects the current flowing through secondary battery 10 by detecting the output voltage of hall element 15. Current detection circuit 40 outputs the detected current value of secondary battery 10 to control unit 50. When secondary battery 10 is formed of a series/parallel circuit of the plurality of battery cells, current detection circuit 40 detects the current for each current path.

Temperature detection circuit 45 estimates a resistance value from the voltages at both ends of thermistor Rt or the current value flowing through thermistor Rt, and estimates the temperature from the estimated resistance value. Temperature detection circuit 45 outputs, to control unit 50, the detected temperature value of secondary battery 10.

Storage unit 60 holds a program executed by control unit 50 and data used in the program. Storage unit 60 includes SOC-OCV table 61, correction table 62, and SOH/FCC (full charge capacity) holding unit 63. SOC-OCV table 61 is a table showing the relationship between the SOC of the battery cells constituting secondary battery 10 and the OCV (open circuit voltage) of the battery cells. SOC-OCV table 61 is created from the data of the SOC and OCV that are obtained when the charging rate of the battery cells increases gradually from the state of 0% in a previous experiment or simulation.

Correction table 62 is a table showing correction coefficients that are used for an SOC correction processing (described later) and/or an SOH (state of health) correction processing (described later). SOH/FCC (full charge capacity) holding unit 63 temporarily holds the SOH (degree of deterioration) and/or FCC (full charge capacity).

Control unit 50 includes current-integration estimation unit 51, open-circuit voltage estimation unit 52, SOC determination unit 53, SOH estimation unit 54, FCC update unit 55, and communication unit 56.

Current-integration estimation unit 51 estimates the SOC of the battery cells by integrating the values of the currents flowing through battery cells S1 to Sn that are detected by current detection circuit 40. Specifically, the SOC is estimated using the following (equation 1).

SOC=SOC₀±(Q/FCC)×100 (equation 1).

SOC₀ shows an SOC before the start of charge/discharge, Q shows an integrated current value, and FCC shows a full charge capacity. The + shows charge, and − shows discharge.

Open-circuit voltage estimation unit 52 estimates the OCV of battery cells S1 to Sn on the basis of a value that includes at least the value of measured voltage Vd of battery cells S1 to Sn and indicates the state of battery cells S1 to Sn, and identifies the SOC corresponding to the OCV. In the present exemplary embodiment, current value I and internal resistance value R in addition to measured voltage value Vd are used as the value indicating the state of battery cells S1 to Sn. The calculation equation of the OCV is described using the following (equation 2).

OCV=Vd±I×R (equation 2).

As current value I, an average current value for 10 s is used, for example. Internal resistance value R may be specified with reference to previously determined map information, or may be estimated from the I-V relationship between the current value and voltage value that are detected during charge/discharge. (Equation 2) is an example of the OCV estimation equation, and another estimation equation may be used. For example, an estimation equation including temperature correction may be used.

Open-circuit voltage estimation unit 52 identifies the SOC corresponding to the calculated OCV with reference to SOC-OCV table 61. Specifically, open-circuit voltage estimation unit 52 reads the SOC corresponding to the calculated OCV with reference to SOC-OCV table 61. When the OCV having the same value as that of the calculated OCV is not described in SOC-OCV table 61, open-circuit voltage estimation unit 52 reads at least two SOCs corresponding to at least two OCVs adjacent to the calculated OCV, and calculates the SOC corresponding to the calculated OCV by interpolation. For example, open-circuit voltage estimation unit 52 reads two SOCs corresponding to two OCVs before and after the calculated OCV, and performs linear interpolation.

SOC determination unit 53 employs the SOC estimated by open-circuit voltage estimation unit 52 while secondary battery 10 is being neither charged nor discharged. While secondary battery 10 is being neither charged nor discharged, current does not flow through secondary battery 10 and hence the SOC cannot be calculated by the current integration method. While secondary battery 10 is being charged or discharged, SOC determination unit 53 employs the SOC estimated by current-integration estimation unit 51 without change, or employs an SOC obtained by correcting the former SOC using the SOC estimated by open-circuit voltage estimation unit 52.

The value of the SOC estimated by the OCV method is more apt to fluctuate than the value of the SOC estimated by the current integration method. In the current integration method, the integrated value of the current is used, and hence the value is more stable than in the OCV method that is directly affected by the variation in current value. In a secondary battery mounted in a vehicle, the current value becomes irregular because of the irregular variation in power consumption or the irregular switch between the charge and discharge. Particularly in an urban area, a traffic jam or a waiting for the lights to change occurs frequently. Therefore, the power consumption varies, or the switch between the charge and discharge occurs every several seconds. When secondary battery 10 is used, therefore, the SOC estimated by the current integration method is used essentially.

When the characteristic of the current detection element is ideal, the SOC estimated by the current integration method is used as it is. However, generally, an offset error originating in the manufacturing variation or temperature characteristic occurs in the current detection element. Such an offset error is slight, but the error is accumulated with time in the current integration method. In the OCV method, the offset error is not accumulated.

When the difference between the value of the SOC estimated by current-integration estimation unit 51 and that of the SOC estimated by open-circuit voltage estimation unit 52 exceeds a set value, SOC determination unit 53 corrects the value of the former SOC so that the value approaches the value of the latter SOC. In principle, SOC determination unit 53 employs the value of the SOC calculated by the current integration method, which is a stable value. In order to reduce the influence of the accumulated error of the current detection element, SOC determination unit 53 makes the value of the SOC approach the value of the SOC calculated by the OCV method. Thus, the estimation accuracy of the SOC can be improved.

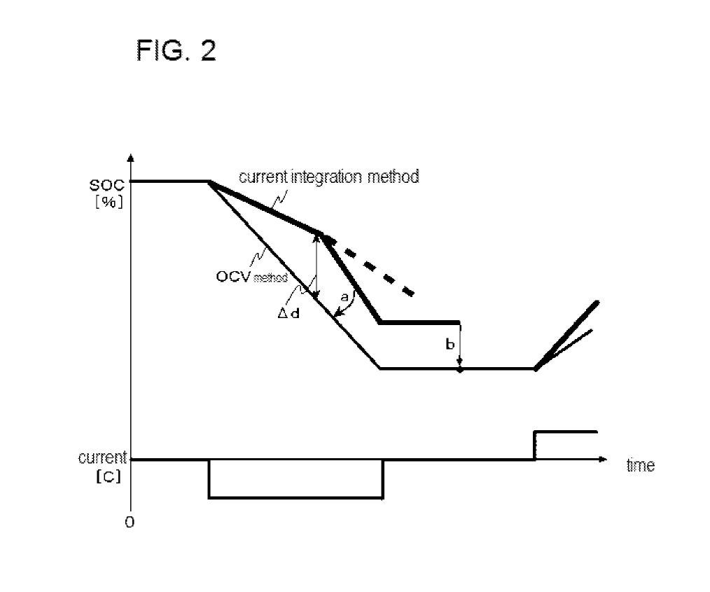

FIG. 2 is a diagram showing an example of the SOC determination processing by SOC determination unit 53. When the ignition switch of the vehicle is in the ON state, the SOC estimation is executed periodically (for example, every 10 ms, or 1 s). In FIG. 2, the upper part shows the progression (thin line) of the SOC estimated by the OCV method and the progression (thick line) of the SOC estimated by the current integration method, and the lower part shows the progression of the current.

In the state where current does not flow, the SOC is estimated only by the OCV method, and the estimated SOC is employed. When discharge is started and the current value becomes negative after the state, the SOC is estimated by both of the OCV method and the current integration method. In the discharge state, the SOC estimated by the current integration method is essentially employed.

The difference between the value of the SOC estimated by the OCV method and that of the SOC estimated by the current integration method becomes large with time. When difference value Δd exceeds the set value, the correction processing of the value of the SOC estimated by the current integration method is started. Specifically, the current value used for the current integration is corrected. For example, current value Iq to be added in the current integration method is calculated using the following (equation 3).

Iq=Id×α (equation 3).

Id shows an actual measured value of current, and α shows a correction coefficient. Correction coefficient α may be a fixed value, or may be a variable value varying depending on difference value Δd. A table showing the relationship between difference value Δd and correction coefficient α may be prepared as correction table 62. As the set value, and correction coefficient α or the table that shows the relationship between ASOC and correction coefficient α, values calculated on the basis of the experiment or simulation has been performed by the designer can be used.

In FIG. 2, the start of the correction processing prevents the SOC estimated by the current integration method from progressing on the dotted line, and makes the SOC approach the SOC estimated by the OCV method (arrow a). Then, the discharge is completed, and the current flow substantially stops. When this state continues for a certain period, the SOC estimation by the current integration method is stopped, and the SOC estimated by the OCV method is employed (arrow b).

Then, when the charge is started and the current value becomes positive, the SOC estimation by the current integration method is restarted, and the SOC is estimated by both of the OCV method and the current integration method. In the charge state, the SOC estimated by the current integration method is essentially employed. Also in the charge state, the above-mentioned correction processing is started similarly to the discharge state.

The process returns to FIG. 1. SOH estimation unit 54 estimates the SOH of battery cells S1 to Sn, on the basis of the variation value of the SOC employed by SOC determination unit 53 and the integrated current value in the time period required for the variation. The SOH is a typical indicator showing the degree of deterioration of the battery, and is used as an index of the battery replacement or the like. For example, the SOH can be estimated using the following (equation 4) and (equation 5).

SOH=FCC/Cd×100 (equation 4).

FCC=(Qt/ΔSOC)×100 (equation 5).

Cd shows an initial capacity (design capacity) of the battery, ΔSOC shows a variation value of the SOC, and Qt shows a section capacity (integrated current value) required for ΔSOC. In other words, the SOH is defined as the ratio of full charge capacity FCC to initial capacity Cd.

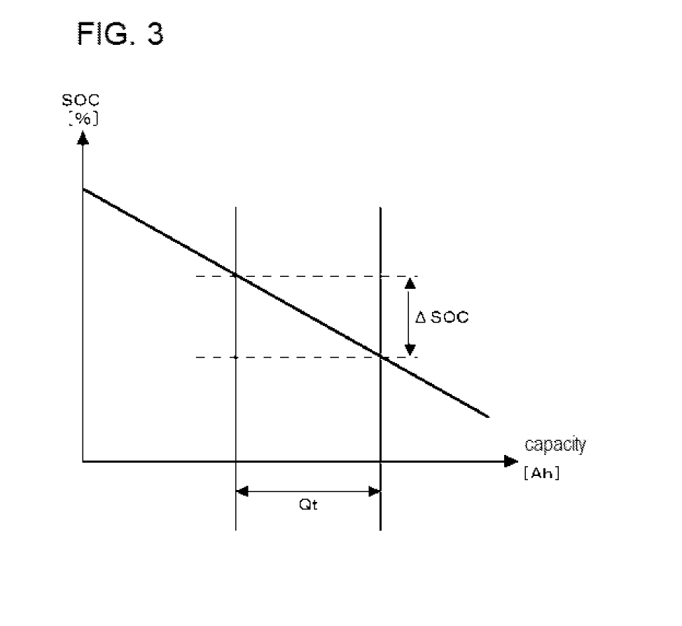

FIG. 3 is a diagram showing the relationship between the discharge capacity and the SOC during discharge. During discharge, the value of the SOC decreases as the discharge capacity increases. During charge, inversely, the value of the SOC increases as the charge capacity increases. When the SOC employed by SOC determination unit 53 varies by a set value (e.g. 10%), SOH estimation unit 54 specifies charge/discharge capacity in the section required for the variation, and estimates the SOH using (equation 4) and (equation 5). The charge/discharge capacity in the section can be specified on the basis of the integrated current value in the section.

In order to increase the estimation accuracy of the SOH, section capacity Qt may be corrected. For example, temperature correction and/or current correction may be applied to section capacity Qt calculated by time integration of the detected current value, for example. SOH estimation unit 54 calculates section capacity Qt′ after the correction using the following (equation 6) and (equation 7).

Qt′=Qt×αt (equation 6).

Qt′=Qt×αi (equation 7).

Here, αt shows a temperature correction coefficient, and αi shows a current correction coefficient.

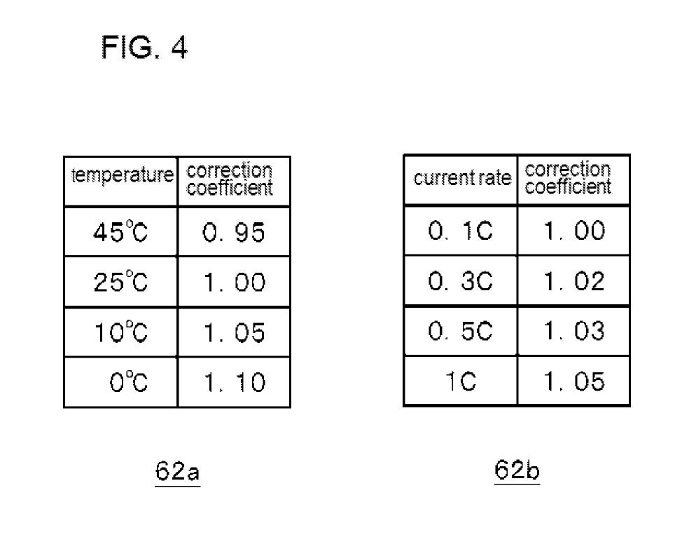

FIG. 4 shows temperature correction table 62a and current correction table 62b. Temperature correction table 62a is a table showing the relationship between the temperature value detected by temperature detection circuit 45 and temperature correction coefficient αt. Current correction table 62b is a table showing the relationship between the current value detected by current detection circuit 40 and current correction coefficient αi.

SOH estimation unit 54 specifies temperature correction coefficient at on the basis of the detected temperature value with reference to temperature correction table 62a. SOH estimation unit 54 also specifies current correction coefficient αi on the basis of the detected current value with reference to current correction table 62b. Section capacity Qt may be multiplied by the two correction coefficients in any sequence.

Upon estimating the SOH, SOH estimation unit 54 updates the SOH held in SOH/FCC holding unit 63 to the newly estimated SOH. Specifically, SOH estimation unit 54 overwrites the presently held SOH with the new SOH.

The process returns to FIG. 1. As shown in (equation 4) and (equation 5), the FCC is estimated during the calculation for the SOH estimation. SOH estimation unit 54 updates the FCC held in SOH/FCC holding unit 63 to the FCC newly estimated in association with the SOH estimation.

As shown in (equation 1), current-integration estimation unit 51 estimates the present SOC by adding, to the SOC at the start of the current integration, a value obtained by normalizing integrated current value Q with respect to full charge capacity FCC. Therefore, the accuracy of the SOC estimated by the current integration method is affected by the FCC. Generally, the SOH estimation processing is not frequently executed, and the frequency is lower than at least the frequency of the SOC estimation. For example, the SOH estimation processing is executed whenever the ignition switch is turned on, or once per day.

However, strictly speaking, battery cells S1 to Sn are degraded also by the charge/discharge of secondary battery 10 during travelling of the vehicle. Therefore, the SOH increases and FCC decreases. In the present exemplary embodiment, the SOH estimation processing is executed in parallel with the SOC estimation processing during the charge/discharge of secondary battery 10. Thus, the FCC used in the SOC estimation by the current integration method can be always kept in the newest state.

In the present exemplary embodiment, the SOH estimation processing is triggered by a certain amount of SOC variation. In other words, SOH estimation unit 54 estimates the SOH and FCC whenever the SOC determined by SOC determination unit 53 varies by a set value. Whenever SOH estimation unit 54 estimates the SOH, FCC update unit 55 updates the FCC used in the SOC estimation processing by the current integration method.

Communication unit 56 transmits, to ECU 500, the SOC determined by SOC determination unit 53 and the SOH estimated by SOH estimation unit 54. Battery management device 20 is connected to ECU 500 via a network such as a controller area network (CAN).

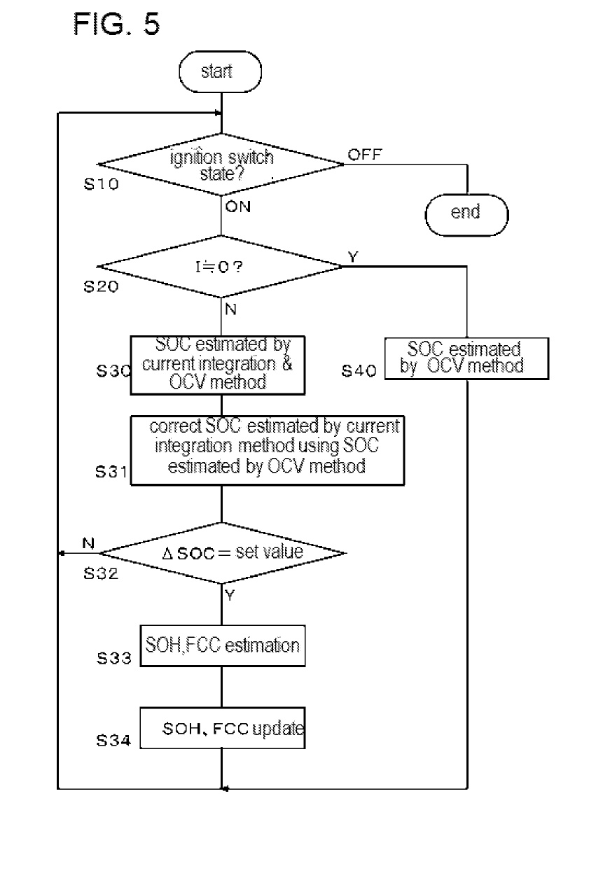

FIG. 5 is a flowchart for illustrating the SOC estimation processing by battery management device 20 in accordance with the exemplary embodiment of the present invention. When the ignition switch is in the ON state (ON in S10), SOC determination unit 53 determines whether or not current value I of secondary battery 10 is approximately zero (S20). When current value I is approximately zero (Y in S20), the SOC estimation is executed only by the OCV method, and SOC determination unit 53 employs the SOC estimated by the OCV method without change (S40). Then, the process goes to step S10.

When current value I of secondary battery 10 is not approximately zero, (namely, during charge/discharge) (N in S20), the SOC is estimated by both of the current integration method and the OCV method (S30). SOC determination unit 53 corrects the SOC estimated by the current integration method using the SOC estimated by the OCV method (S31).

When variation amount ΔSOC of the SOC arrives at the set value (Y in S32), SOH estimation unit 54 estimates the SOH and FCC (S33). SOH estimation unit 54 updates the SOH and FCC in SOH/FCC holding unit 63 to the estimated SOH and FCC. FCC update unit 55 updates, to the estimated FCC, the FCC used in the SOC estimation by the current integration method (S34). Then, the process goes to step S10.

When variation amount ΔSOC of the SOC does not arrive at the set value (N in S32), steps S33 and S34 are skipped. When the ignition switch is turned off (OFF in S10), battery management device 20 finishes the SOC estimation processing.

In the external charge period in which secondary battery 10 is charged from an external AC power source via charging plug 400, the SOC estimation processing is not executed. Therefore, the SOH estimation processing is not executed, either. Generally, the external charge is a constant current charge (CC charge) until arrival at a set voltage. Therefore, while the vehicle is travelling, the necessity to execute the SOC estimation processing in the external charge period is small. At the completion of the charge, the SOC and SOH are estimated. In this case, as variation amount ΔSOC of the SOC used for the SOH estimation, the difference between the SOC at the start of the charge and the SOC at the completion of the charge is used. As section capacity Qt, charge capacity from the start of the charge to the completion of the charge is used.

In the present exemplary embodiment, as described above, the SOH estimation processing is executed in parallel with the SOC estimation processing by the current integration method, and the FCC used in the current integration method is updated to the FCC corresponding to the SOH. Thus, the accuracy of the SOC estimated by the current integration method can be improved compared with the conventional art. When the SOC that is estimated by the current integration method having a higher accuracy than that of the conventional method is corrected using the SOC estimated by the OCV method, the estimation accuracy can be further improved.

Thus, the present invention has been described using the exemplary embodiment. The persons skilled in the art understand that the exemplary embodiment is an example, the combination of the components and processing processes can be variously modified, and such modifications are also included in the scope of the present invention.

The exemplary embodiment of the present invention has described a power supply that is mounted as an on-vehicle power source in a vehicle. However, the application of the power supply is not limited to the vehicle. The power supply is also applicable to an energy storage system. When the power supply is applied to the energy storage system, step 10 in FIG. 5 is not required.

In the exemplary embodiment, SOH estimation unit 54 estimates the FCC using the ratio between variation amount ΔSOC of the SOC and section capacity Qt. From this point of view, in the region having a low SOC, a part exists where the ratio between the SOC and the capacity becomes unstable. Therefore, the designer previously recognizes the relationship between the SOC and capacity of the battery to be employed in the experiment or simulation, and specifies the region (e.g. 30% to 90%) of the SOC where the ratio between the SOC and capacity is stable. When the value of the SOC exists in the region, SOH estimation unit 54 estimates the SOH. When the value of the SOC does not exist in the region, and SOH estimation unit 54 skips the SOH estimation. Thus, the estimation accuracy of the SOH can be improved.

The invention related to the present exemplary embodiment may be specified with the following items.

### (Item 1)

A battery management device includes:
a current-integration estimation unit for estimating the SOC of a battery by integrating the value of the current flowing through the battery;
an open-circuit voltage estimation unit for estimating the open-circuit voltage value of the battery from a value that includes at least the measured voltage value of the battery and indicates the state of the battery, and identifying the SOC corresponding to the open-circuit voltage value;
an SOC determination unit that, while the battery is being neither charged nor discharged, employs the SOC estimated by the open-circuit voltage estimation unit, and, while the battery is being charged or discharged, employs the SOC estimated by the current-integration estimation unit without change or after correction using the SOC estimated by the open-circuit voltage estimation unit; and
an SOH estimation unit that, in parallel with the SOC estimation, estimates the SOH of the battery based on the variation value of the SOC employed by the SOC determination unit and the integrated current value in the time period required for the variation.

### (Item 2)

The battery management device according to item 1 further includes a full-charge-capacity update unit for updating the full charge capacity that is used in SOC estimation by the current-integration estimation unit to the full charge capacity that is newly estimated in association with the SOH estimation by the SOH estimation unit. The current-integration estimation unit estimates a present SOC by adding, to the SOC at the start of the current integration, a value obtained by normalizing the integrated current value with respect to the full charge capacity.

### (Item 3)

The battery management device according to item 2 in which
whenever the SOC employed by the SOC determination unit varies by a set value, the SOH estimation unit estimates the SOH, and
whenever the SOH estimation unit estimates the SOH, the full-charge-capacity update unit updates the full charge capacity used in the SOC estimation by the current-integration estimation unit.

### (Item 4)

A power supply includes:
a battery for storing energy for travelling or a load; and
a battery management device according to one of items 1 to 3 for managing the battery.

### (Item 5)

An SOC estimation method includes:
a current-integration estimation step of estimating the SOC of a battery by integrating the value of the current flowing through the battery, specifically, estimating a present SOC by adding, to the SOC at the start of the current integration, a value obtained by normalizing the integrated current value with respect to the full charge capacity of the battery;
an open-circuit voltage estimation step of estimating the open-circuit voltage value of the battery from a value that includes at least the measured voltage value of the battery and indicates the state of the battery, and identifying the SOC corresponding to the open-circuit voltage value;
an SOC determination step of, while the battery is being neither charged nor discharged, employing the SOC estimated by the open-circuit voltage estimation step, and, while the battery is being charged or discharged, employing the SOC estimated by the current-integration estimation step without change or after correction using the SOC estimated by the open-circuit voltage estimation step;
an SOH estimation step of estimating the SOH of the battery based on the variation value of the employed SOC and the integrated current value in the time period for the variation; and
a full-charge-capacity update step of updating the full charge capacity based on the estimated SOH.
   Any combination of the components, and a conversion of the expression of the present invention into the method, device, system, recording medium, or computer program are also effective as the aspect of the present invention.

### REFERENCE MARKS IN THE DRAWINGS

S1, S2 battery cell
10 secondary battery
15 hall element
20 battery management device
30 voltage detection circuit
40 current detection circuit
45 temperature detection circuit
50 control unit
51 current-integration estimation unit
52 open-circuit voltage estimation unit
53 SOC determination unit
54 SOH estimation unit
55 FCC update unit
56 communication unit
60 storage unit
61 SOC-OCV table
62 correction table
63 SOH/FCC holding unit
100 power supply
200 inverter
300 motor for travelling
400 charging plug
500 ECU

1. A battery management device comprising:
a current-integration estimation unit for estimating an SOC (state of charge) of a battery by integrating a value of a current flowing through the battery;
an open-circuit voltage estimation unit for estimating an open-circuit voltage value of the battery from a value that indicates a state of the battery and includes at least a measured voltage value of the battery, and determining an SOC corresponding to the open-circuit voltage value;
an SOC determination unit that, while the battery is being neither charged nor discharged, employs the SOC estimated by the open-circuit voltage estimation unit, and, while the battery is being charged or discharged, employs the SOC estimated by the current-integration estimation unit without change or after correction using the SOC estimated by the open-circuit voltage estimation unit; and
an SOH (state of health) estimation unit that, estimates an SOH of the battery based on a variation value of the SOC employed in parallel with estimation of the SOC by the SOC determination unit and an integrated current value in a time period taken for the variation.

2. The battery management device according to claim 1, further comprising
a full-charge-capacity update unit for updating a full charge capacity that is used in the SOC estimation by the current-integration estimation unit to a full charge capacity that is newly estimated in association with SOH estimation by the SOH estimation unit,
wherein the current-integration estimation unit estimates a present SOC by adding, to an SOC at a start of current integration, a value obtained by normalizing the integrated current value with respect to the full charge capacity.

3. The battery management device according to claim 2, wherein
whenever the SOC employed by the SOC determination unit varies by a set value, the SOH estimation unit estimates an SOH, and
whenever the SOH estimation unit estimates the SOH, the full-charge-capacity update unit updates the full charge capacity used in the SOC estimation by the current-integration estimation unit.

4. A power supply comprising:
a battery for storing energy for travelling or a load; and
a battery management device according to claim 1 for managing the battery.

5. An SOC estimation method comprising:
a current-integration estimation step of estimating an SOC of a battery by integrating a value of a current flowing through the battery, wherein a present SOC is estimated by adding, to an SOC at a start of current integration, a value obtained by normalizing an integrated current value with respect to a full charge capacity of the battery;
an open-circuit voltage estimation step of estimating an open-circuit voltage value of the battery from a value that indicates a state of the battery and includes at least a measured voltage value of the battery, and determining an SOC corresponding to the open-circuit voltage value;
an SOC determination step of, while the battery is being neither charged nor discharged, employing the SOC estimated by the open-circuit voltage estimation step, and, while the battery is being charged or discharged, employing the SOC estimated by the current-integration estimation step without change or after correction using the SOC estimated by the open-circuit voltage estimation step;
an SOH estimation step of estimating an SOH of the battery based on a variation value of the employed SOC and the integrated current value in a time period of the variation; and
a full-charge-capacity update step of updating the full charge capacity based on the estimated SOH.

6. A power supply comprising:
a battery for storing energy for travelling or a load; and
a battery management device according to claim 2 for managing the battery.

7. A power supply comprising:
a battery for storing energy for travelling or a load; and
a battery management device according to claim 3 for managing the battery.
